(19) United States
(12) Patent Application Publication
(10) Pub. No.: US 2007/0257263 A1
(43) Pub. Date: Nov. 8, 2007

(54) DISPLAY DEVICE

(75) Inventors: Shintaro Enomoto, Yokohama-shi (JP); Yukitami Mizuno, Tokyo (JP); Nobuyoshi Saito, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/736,740

(22) Filed: Apr. 18, 2007

(30) Foreign Application Priority Data
Apr. 20, 2006 (JP) P2006-116958

(51) Int. Cl. H01L 29/04

(52) U.S. Cl. 257/72

(57) ABSTRACT

A display device includes a first substrate; a first electrode and a second electrode placed on the first substrate; a second substrate separately placed from and facing with the first substrate; a third electrode placed on the second substrate; a first layer placed between the first and second substrates, being on the first substrate, and including a luminescent material which becomes luminous in response to electrochemical oxidation or reduction; a second layer placed between the first and second substrates, being on the second substrate, and including a coloring material which discolors in response to electrochemical oxidation or reduction; and a third layer placed between the first and second layers, transmitting none of or few oxidizing species or reducing species in the luminescent material, and having ion conductivity and electron conductivity.

### CROSS REFERENCE TO RELATED APPLICATIONS

This application is based upon and claims the benefit of priority from prior Japanese Patent Application No. 2006-116958 filed on Apr. 20, 2006, the entire contents of which are incorporated by reference herein.

### BACKGROUND OF THE INVENTION

1. Field of the Invention

This invention relates to a display device which includes an ECL material featuring an electrochemiluminescence (ECL) effect and an EC material featuring an electrochromic effect.

2. Description of the Related Art

Semi-transmissive LCDs which can offer both reflective and luminous indications become popular as display devices for mobile phones used indoors and outdoors. In the semi-transmissive LCD, images are indicated by reflection via an uneven reflecting layer at a part of a pixel, and by light emission via a transmissive layer at a part except for the uneven reflecting layer. A backlight is placed under the transmissive layer in order to emit light. For instance, refer to JP-A 2003-241188 (KOKAI) (pages 3 to 5, and FIG. 3).

The foregoing display device can offer bright and easily viewable indications depending upon luminescence of the backlight. However, a reflector should be provided for the reflective indication to overcome restrictions related to indication principles of the liquid crystal, and one pixel should be divided into two parts for the reflective indication and the luminous indication. Therefore, it is very difficult to provide an ensured indication having a sufficient contrast and easily visible.

Electrochromic displays (ECD) are available as display devices offering high contrast reflective indications. The electrochromic display is constituted by an EC material and an electrolyte which are placed between two electrodes (refer to JP-A 2003-21848 (KOKAI) (pages 4 to 14, and FIG. 1)). An EC material discolors in response to the electrochemical oxidation or reduction. However, the ECD offers only the reflective indication, which is not clear at dimly lit locations.

This invention is contemplated in order to provide a display device which can assure bright and clear indications.

### BRIEF SUMMARY OF THE INVENTION

According to a first aspect of the embodiment of the invention, there is provided a display device including a first substrate; a first electrode and a second electrode placed on the first substrate; a second substrate separately placed from and facing with the first substrate; a third electrode placed on the second substrate; a first layer placed between the first and second substrates, being on the first substrate, and including a luminescent material which becomes luminous through electrochemical oxidation or reduction; a second layer placed between the first and second substrates, being on the second substrate, and including a coloring material which discolors in response to electrochemical oxidation or reduction; and a third layer placed between the first and second layers, transmitting none of or few oxidizing species or reducing species in the luminescent material, and having ion conductivity and electron conductivity.

In accordance with a second aspect of the embodiment of the invention, there is provided a display device including: a first substrate; a first electrode and a second electrode placed on the first substrate; a second substrate separately placed from and facing with the first substrate; a third electrode placed on the second substrate; a first layer placed between the first and second substrates, being on the first substrate, and including a luminescent material which becomes luminous in response to electrochemical oxidation or reduction; a second layer placed between the first and second substrates, being on the second substrate, and including a coloring material which discolors in response to electrochemical oxidation or reduction; and a third layer placed between the first and second layers, and including a cross-linker transmitting none of or few oxidizing species or reducing species in the luminescent material.

### BRIEF DESCRIPTION OF THE SEVERAL VIEWS OF THE DRAWINGS

FIG. 1 is a cross section of a display device according to a first embodiment of the invention;

FIG. 2 is a cross section of a display device according to a second embodiment of the invention;

FIG. 3 is a cross section of a display device according to a third embodiment of the invention;

FIG. 4 shows how reflective indications are offered in the embodiments of the invention; and

FIG. 5 shows how luminous indications are offered in the embodiments of the invention.

### DETAILED DESCRIPTION OF THE INVENTION

Display device according to embodiments of the present invention will be described in detail hereinafter.

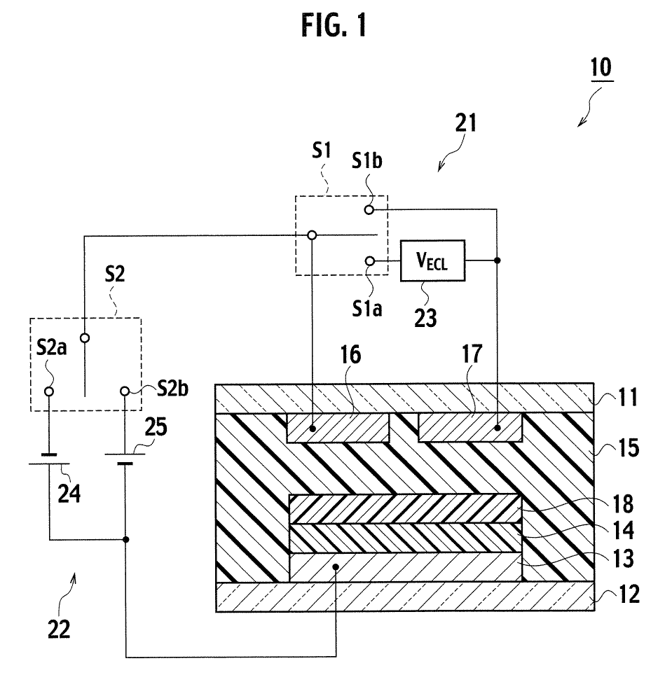

According to a first embodiment shown in FIG. 1, a display device 10 includes a first substrate 11; a first electrode 16 and a second electrode 17 placed on the first substrate 11; a second substrate 12 placed apart from and facing with the first substrate 11; and a third electrode 13 placed on the second substrate 12. Although the display device 10 includes a plurality of pixels, only one pixel is shown in FIG. 1.

A first layer 15 is placed between the first substrate 11 and the second substrate 12, being on the first substrate 11, a first electrode 16 and a second electrode 17. A first layer 15 is made of a luminescence material and an electrolyte. The luminescence material emits light in response to the electrochemical oxidation or reduction. A second layer 14 is placed between the first substrate 11 and the second substrate 12, being on a third electrode 13 on the second substrate 12, and includes a coloring material which discolors in response to the electrochemical oxidation or reduction.

A third layer 18 is provided between the second layer 14 and the first layer 15, and has ion conductivity and electron conductivity. The term “ion conductivity” represents a property to conduct ions necessary for the oxidation or reduction of an EC material of the second layer 14 (an EC layer demonstrating electrochromic effect to be described later). The third layer 18 transmit none of or few transmits molecules, oxidizing species (cation radicals) or reducing species (anion radicals) of the luminescence material. In the first embodiment, the third layer 18 is as large as the second layer 14.

A set of the first, second and third electrodes 16, 17 and 13 constitute one pixel. The first and second electrodes 16 and 17 have substantially the same size. The third electrode 13 is patterned for every pixel.

The first layer 15 includes an electrochemiluminescence (ECL) material which emits light when deactivated after being activated for the electrochemical oxidation or reduction in response to voltage application.

In response to the voltage application, the ECL material in the first layer 15 is oxidized near the first and second electrodes 16 and 17 and is changed to oxidizing species (cation radicals), or is reduced and is changed to reducing species (anion radicals). The cation radicals and anion radicals get together, and activate the ECL material. The ECL material emits light when it is deactivated. The display device 10 offers the luminescent indication using the foregoing phenomenon. The first layer 15 preferably includes support salt which assists the oxidation and reduction of the ECL material of the first layer 15.

Further, the second layer 14 includes a coloring agent or an EC material which discolors when the electrochemical oxidation or reduction occurs in response to the voltage application.

When reduced, the EC material of the second layer 14 colors or becomes colorless. On the contrary, when oxidized, the EC material becomes colorless or colors. For instance, when WO₃ is used, the EC material becomes colorless and transparent in response to the oxidation. On the contrary, the EC material colors and becomes blue in response to the reduction. The reflective indication is offered using the foregoing phenomenon.

The display device 10 also includes switches S1 and S2, which are used to select the luminescent indication and the reflective indication. Specifically, the display device 10 is provided with a first voltage applicator 21 to apply the voltage to the first layer 15, and a second applicator 22 to apply the voltage to the second layer 14.

The first voltage applicator 21 is constituted by the first and second electrodes 16 and 17, and an AC power source 23. When the switch S1 is set to a first terminal S1a, an AC voltage will be applied between the first and second electrodes 16 and 17, so that the ECL material of the first layer 15 to become luminescent.

The second voltage applicator 22 is constituted by the third electrode 13, and DC power sources 24 and 25 having opposite polarities. When the switch SI is set to a second terminal S1b, the first and second electrodes 16 and 17 have the same potential. Further, when the switch S2 is set to a first terminal S2a or a second terminal S2b, either the DC power source 24 or the DC power source 25 will be selected, so that the EC material of the second layer 14 will color or become transparent.

A user can select either the luminescent indication or the reflective indication depending upon where the display device 10 is operated. In response to the operation of the switch S1 or S2, the first or second voltage applicator 21 or 22 applies the predetermined voltage to the first to third electrodes, so that the luminescent indication or the reflective indication will be performed. For instance, when the luminescent indication is selected, the AC voltage will be applied between the first and second electrodes 16 and 17. On the contrary, the voltage applied to the third electrode 13 will be controlled in the case of the reflective indication.

Referring to FIG. 1, the third electrode 13, the second layer 14, and the third layer 18 are patterned for every pixel.

In the first embodiment, the second layer 14 is solid while the first layer 15 is solid or liquid. The second layer 14 and the first layer 15 are preferably solid in order to restrain performance deterioration due to leakage or evaporation of a solvent.

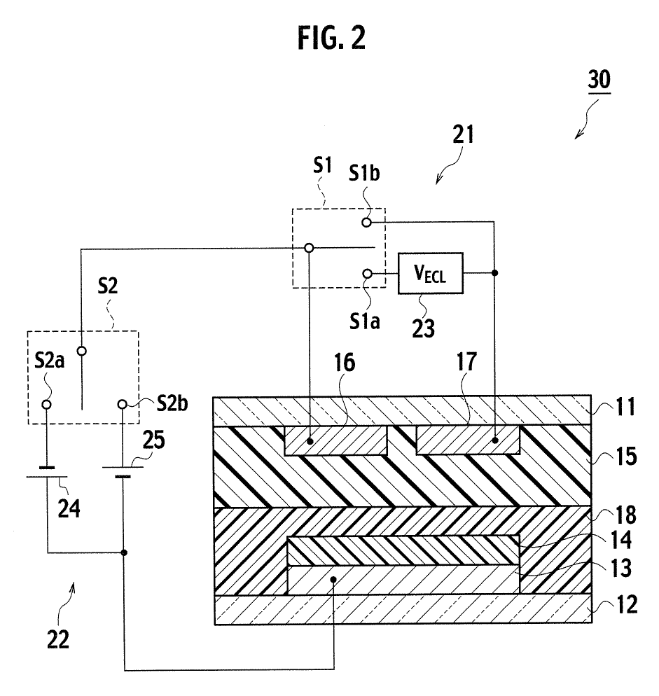

In a second embodiment, a display device 30 is configured as shown in FIG. 2. The display device 30 differs from the display device 10 in the following respects. Specifically, the third layer 18 extends over the second layer 14 and the second substrate 12.

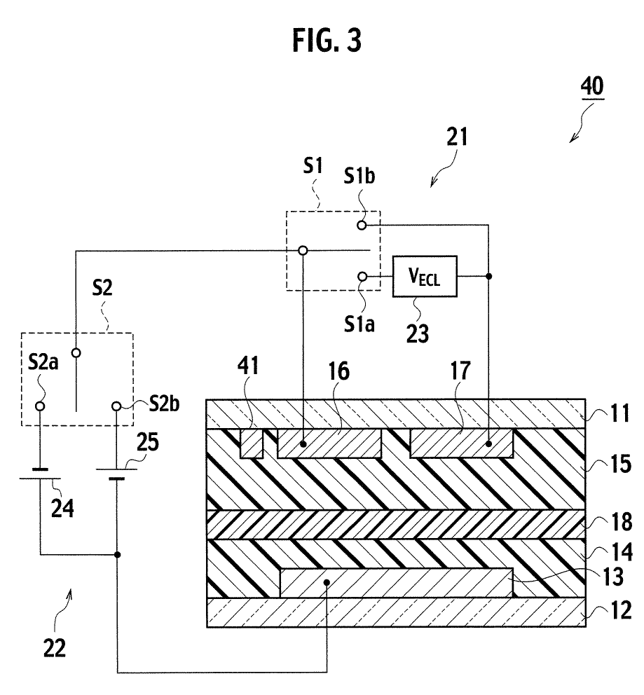

According to a third embodiment, a display device 40 is configured as shown in FIG. 3. The following describe how the display device 40 differs from the display device 10. The second and third layers 14 and 18 are not patterned for respective pixels, but extend over the third electrode 13 and the second substrate 12. Further, a reference electrode 41 is placed on the first substrate 11. Alternatively, reference electrodes 41 may be provided at ends of respective pixels, or at one or more positions in the display device 30.

As shown in FIG. 3, the third electrode 13 is patterned for each pixel while the second and third layers 14 and 18 are not patterned for respective pixels but are used in common for a plurality of pixels.

The display devices 10 and 30 shown in FIG. 1 and FIG. 2 do not include any reference electrode. Alternatively, they may include the reference electrode.

In the third embodiment, the display device 40 (including the reference electrode 41) will operate as follows.

For the reflective indication, the voltage will be applied to the third electrode 13 in order to produce a potential for reducing or oxidizing the EC material. First of all, the first and second electrodes 16 and 17 are set to the same potential. A polarity of the voltage to be applied the third electrode 13 is reversed. For instance, the EC material of the second layer 14 becomes colorless in response to the oxidation, and colors in response to the reduction.

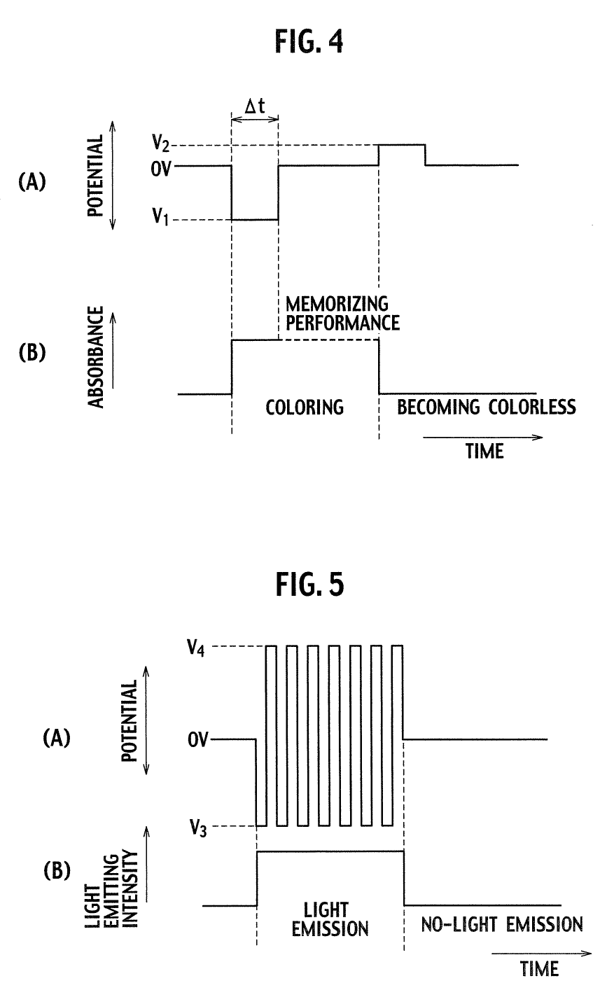

In FIG. 4, the potential of the third electrode 13 is shown at (A) while an example of absorbance is shown at (B) when the second layer 14 (EC layer) colors or becomes colorless. The absorbance is increased as the EC material colors while it is decreased as the EC material becomes colorless. For instance, when the potential of the third electrode 13 is set to be V₁ for a preset period of time Δt (V₁ being a negative reduction potential of the EC material), the EC material of the second layer 14 is reduced, and colors (absorbance being large). Even when the potential of the third electrode 13 is set to zero (0) after lapse of the preset period of time Δt, the EC material remains colored since it memorizes its previous state. When a potential V₂ (which is a positive oxidation potential of the EC material) is applied as the potential of the third electrode 13, the EC material will be oxidized and become colorless (absorbance being small).

When the reference electrode 41 is used, the potential of the third electrode 13 (for coloring and losing color) may be set to the potential of the reference electrode 41.

Ions produced by the support salt which is contained in the first and third layers 13 and 18 and is dissociated from them may have to do with the EC reaction (oxidation/reduction) for the reflective indication, which depends upon what is used as the EC material. For instance, if the second layer 14 is made of WO₃ as the EC material, a material containing Li⁺ (e.g., LiCF₃SO₃ as the support salt) should be included in the first layer 15 (containing the ECL material) or the third layer 18. In this case, the EC reaction is expressed by a formula (1).

WO₃+xe+xLi⁺<=>LiₓWO₃ (1)

In the oxidation expressed at the left-hand side of the formula (1), the EC material becomes colorless (transparent). In the reduction at the right-hand side of the formula (1), the EC material discolors (becomes blue).

For the luminous indication, no voltage is applied to the third electrode 13, but the AC voltage is applied between the first electrode 16 and the second electrode 17. FIG. 5 shows the potential of the first electrode 16 with respect to the reference electrode 41 at (A), and shows the absorbance representing the light emission/non-light emission state of the first layer 15 (ECL layer) at (B). Although not shown, the potential of the second electrode 17 with respect to the reference electrode 41 becomes reverse to the potential of the first electrode 16 during the light-emission state. It is assumed that the AC voltage is applied to the first electrode 16 in order that the potential of the first electrode 16 alternately becomes V₃ and V₄. V₃ is a negative reduction potential at which the ECL material becomes the anion radicals while V₄ is the positive oxidation potential at which the ECL material becomes the cation radicals. When a voltage whose potential is opposite to the AC voltage is applied to the second electrode 17, the ECL material at the electrodes 16 and 17 alternately become the anion radicals and cation radicals. When the anion radicals and cation radicals get together, the ECL material is activated, and emits light while it is being deactivated. In short, the ECL material becomes non-light emission state so long as no voltage is applied. The AC voltage may have a frequency of several ten Hz.

According to the foregoing embodiment, one display device can offer images in two modes by switching the reflective indication over to the luminescent indication and vice versa. The same electrolyte is used for both the luminescent and reflective indications, so that it is possible to prevent the display device from becoming large. This is because a luminescent indication cell and a reflective indication cell are not stacked. Further, since one pixel is not divided into two parts in order to perform the luminescent and reflective indications, a pixel area can be effectively utilized. This enables the display device to offer bright and high-contrast images.

The third layer 18 operates as follows. The third layer 18 has the ion conductivity, and can secure an amount of ions necessary for the reaction of the EC material in the EC layer. Further, the third layer 18 preferably does not transmit the anion radical or cation radical of ECL molecules, or transmits few anion or cation radicals. Therefore, during the luminescent indication, it is possible to prevent a side reaction which is caused when ECL molecules become the anion or cation radicals in the ECL layer and come into contact with the EC layer. This is effective in suppressing degradation of the EC layer.

Still further, the third layer 18 can promote the light-emitting performance of the ECL layer. When the AC voltage is applied to the electrodes 16 and 17 in order to emit light using the ECL effect, the third layer 18 functions as an electron conducting layer via the electrolyte 15 containing ECL molecules. At some time point, ion radicals are produced in the electrode 16, and ion radicals whose polarity is opposite to that of the foregoing ion radicals are produced at an area of the third layer 18 (facing with the electrode 16). At the same time, ion radicals are produced in the electrode 17 and ion radicals whose polarity is opposite to that of the foregoing ion radicals are produced at another area of the third layer 18 (facing with the electrode 17). The ion radicals having the different polarities move in the electrolyte layer 15, knock up against one another, and produce an activator, thereby emitting light. Sometimes, the third layer 18 does not function depending upon materials and conditions of elements (e.g., sizes of electrodes, a thickness of the electrolyte layer, and so on).

The first electrode 16, second electrode 17 and third layer 18 are preferably placed close to one another in order to suppress dispersion of the anion radicals or cation radicals in the ECL layer, and to prevent degradation of the light-emitting efficiency. Specifically, the foregoing components may be preferably separated by 2 μm or less. This can be accomplished by the presence of the third layer 18 which prevents contact of the ECL molecules with the EC layer.

In accordance with the foregoing embodiment in which the third layer 18 is provided, the following are accomplished: the display device can offer the reflective indication and the luminescent indication; the light-emitting performance of the ECL layer can be improved; the EC layer can be protected against degradation; and the luminescent indication is improved, and the reflective indication can be offered for a long period time.

The foregoing display devices can offer bright and high-contrast images for a long period of time.

The following describe detailed configurations of the display devices 10, 30 and 40 shown in FIG. 1 to FIG. 3.

The first substrate 11 is made of glass, plastics (such as PET: polyethylene terephthalate, PEN: polyethylene naphthalate, PES: polyethersulfone, and PC: polycarbonate), and so on. When used as a viewing side, the first substrate 11 is preferably made of a material which absorbs little visible light.

The first and second electrodes 16 and 17 on the first substrate 11 are preferably made of transparent materials. The following transparent materials are applicable for the electrodes 16 and 17 (if the first substrate 11 functions as the viewing side): metal oxide semiconductors such as transition metal oxides (e.g. titanium, zirconium, hafnium, strontium, zinc, tin, indium, yttrium, lanthanum, vanadium, niobium, tantalum, chrome, molybdenum, and tungsten oxide); perovskite such as SrTiO₃, CaTiO₃, BaTiO₃, MgTiO₃ and SrNb₂O₆; or complex oxides or mixture of oxides of the foregoing materials and so on. When functioning as reflective electrodes (placed opposite to the first substrate serving as the viewing side), the electrodes 16 and 17 may be made of Al, Ag or the like.

In order to increase an aperture ratio, the electrodes 16 and 17 are preferably large. In other words, the electrodes 16 and 17 are preferably made of the same material, and have the same size.

The second substrate 12 may be made of the same material as that of the first substrate 11. When serving as the viewing side, the second substrate 12 is preferably made of a material which absorbs little visible light.

The third electrode 13 on the second substrate 12 is preferably made of the same material as that of the first and second electrodes 16 and 17, and is preferably large in order to increase the aperture ratio. Further, the third electrode 13 is preferably positioned to face with the first and second electrodes 16 and 17.

The second layer 14 is placed on the third electrode 13, and is made of the EC material. The following EC materials are usable: inorganic materials such as MnO₂, CoOOH, NiOOH, CuO, RuO₂, Rh₂O₃, IrOₓ, Prussian blue, WO₃, MoO₃, TiO₂, V₂O₅, Nb₂O₅, and AgI; low-molecular organic materials such as viologen group organic materials, ortho-chloranil, 4-benzoyl pyridinium derivatives, luthenium-tris, luthenium-bis, osmium-tris, osmium-pis type transition metal complex, and multiple nuclei complexes; or ruthenium-cis-diaqua-bipyridyl-complexes; coloring agents such as phthalocyanine, naphtha-phthalocyanine, porphyrin, perylene, anthraquinone, azole, chinophthalon, naphthaquinon, cyanine, melochyanine, diphthalocyanine complex, 2,4,5,7-tetranitro-9-fluorene, 2,4,7-trinitro-9-fluorenylidenemalononitrile, tetracyanoquinodimethane; conductive high polymers such as polypyrrole derivates, polythiophene derivatives, polyanilline derivative, polyazlene derivatives, polyisothia-naphthene, poly (N-methylisoindole), poly (dithiene [3,4-b: 3′,4′-d]thiophene), polydiallylamine derivative, polypyrroropyrrole derivatives, Ru complex group conductive high polymer, and so on. The EC materials are not always limited to the foregoing materials.

When the second layer 14 is made of an inorganic material, vapor deposition, sputtering, vapor phase epitaxy, sol-gel process, particulate sintering process or the like will be utilized. If the second layer 14 is made of a low - molecular organic material, vapor deposition, coating (after liquidized) and drying processes will be utilized. Further, if conductive high polymers are used for the second layer 14, they are liquidized, and are coated and dried, or are electrolytically polymerized, so that they will be solidified.

The first layer 15 containing the ECL material is placed between the first substrate 11 and the second substrate 12. By the way, the first and second electrodes 16 and 17 are placed on the first substrate 11 while the third electrode 13 and the second layer 14 are placed on the second substrate 14.

The following ECL materials are usable: polycyclic aromatic compounds such as naphthacene derivatives (rubrene 5,12-diphenyl-naphthacene), anthracene derivatives (9,10-diphenyl anthracene), penthacene derivatives (6,10-diphenyl-penthacene), perifluoranthene derivatives (di-benzotetra (methylphenyl) perifluoranthene, or the like; π electron conjugated high polymers such as poly-paraphenylene vinyl derivatives, polythiophene derivatives, polypara-phenylene derivatives, polyfluorene derivatives, or the like; hetero aromatic compounds such as coumarin; chelate metal complexes such as Ru (bpy)₃₂; organic metal compounds such as tris (2-phenyl-pyridine) iridium; and chelate lanthanoid complexes.

The first layer 15 preferably contains not only the support salt in order to promote oxidation and reduction of the ECL material but also a solvent (for liquid electrolyte) for disassociating the support salt to ions or gelled high polymers (for solid electrolyte) swelled by the foregoing solvent.

The support salt may be tetrabutylammonium perchlorate, hexa-fluoro phosphoric acid kalium, tri-fluoro sulfonic lithium, lithium perchlorate, tetra-fluoro borate tetra-n-buthylammonium, tripopyl amine, tetra-n-butylammonium fluoroborate, or the like.

The solvent may be aceto-nytrile, N,N-dimethyl-formamide, propylene carbonate, o-dichlobenzen, glycerin, water, ethyl-alcohol, propyl alcohol, dimethyl carbonate, ethylene carbonate, γ-butyrolactone, NMP, 2-methylhydrofuran, toluene, tetrahydrofuran, benzonitorile, cyclohexane, n-hexane, acetone, nitrobenzene, 1,3-dioxilan, furan, bebzo trifluoride, or the like.

The gelled high polymers may be polyacrylic-nitrile (PAN), co-polymers of vinylidene fluoride (VDF) and 6-propylene fluoride (HFP), polyethylene oxido (PEO), or the like.

When the first layer 15 is liquid, it is prepared by dissolving the support salt and the ECL material in the solvent. The first layer 15 is filled between the first substrate 11 (carrying the first and second electrodes 16 and 17) and the second substrate 12 (carrying the third electrode 13, the second layer 14 and third layer 18). On the contrary, if the first layer 15 is solid, a gelled high polymer containing the support salt and solvent is coated between the first and second substrates 11 and 12, and is then dried. In this case, an amount of the solvent is more than the support salt.

The third layer 18 is placed between the second layer 14 and the first layer 15. The third layer 18 is an electrolyte, and transmits none of or few cation radicals or anion radicals of the ECL molecules or the ECL material.

In the third layer 18, alkali metal, alkaline earth metal salt or proton acid functions as carriers for moving electric charges. Negative ions are SCN⁻, Cl⁻, Br⁻, I⁻, BF₄⁻PF₆⁻, CF₃SO₃⁻, SbF₆⁻, AsF₆⁻, ClO₄⁻, B(C₆H₅)₄⁻, and so on. Positive ions are alkali metal cations such as Li⁺, Na⁺ and K⁺, or organic cations such as (C₄H₉)₄N⁺, and (C₂H₅)₄N⁺. Most preferably, the third layer 18 contains lithium ions in order to accelerate the movement of electric charges.

The third layer 18 includes materials listed in items (1) or (2).

### (1) Cross-Linker

A cross-linker is a polymer which is produced by chemically combining linear macromolecule polymers, and has a three-dimensional net-like structure. The cross-linker is very tight, and has low solubility to the solvent, and high mechanical strength. Further, the cross-linker transmits few cation or anion radicals.

When the third layer 18 functions as an electrolyte layer, the cross-linker is used as a matrix, and may contain the support salt such as alkali metal, alkaline earth metal salt or proton acid which is dispersed. Further, the cross-linker may include an ion dissociating group.

The following support salt may be dispersed in the cross-linker: lithium fluoride (LiF), sodium iodide (NaI), lithium iodide (LiI), lithium perchlorate (LiClO₄), sodium thiocyanate (NaSCN), trifluoride methan sulfonic acdid lithium (LiCF₃SO₃), sodium fluoro-borate (LiBF₄), hexan fluoro phosphoric acid lithium (LiPF₆), phosphoric acid (H₃PO₃), sulfuric acid (H₂SO₄), trifluoro methane sulfonic acid, tetra-fluoro-ethylene sulfonic acid (C₂F₄(SO₃H)₂), hexan-fluoro butane sulfonic acid (C₄F₆(SO₃H)₄), lithium chloride (LiCl), and lithium bromide (LiBr).

Specifically, the following cross-linkers are available: polyether groups such as polyethylene oxide (PEO), polypropylene oxide, and polybutylene oxide; poly carbonate such as polyethylene carbonate, polypropylene carbonate, or the like; fluorine polymers such as polyvinyliden fluoride, and poly-tetra fluoro ethylene; poly siloxane derivative such as poly-dimethylsiloxane; siloxane derivatives; polyether group such as poly-β-propionic lactone, and polypeptido group such as polyglutamine; polymers such as poly-phosphazane, polyvinyl pyridine, polyacrylonitrile, polyacrylate resin, polyethylene imine, and polyethylene sulfide; and cross-linker polymers containing one of the foregoing materials and a functional group. The functional group which contributes to cross-linking is used to together with one of the foregoing materials. For instance, cinnamoyl group and isocyanate group are usable. The functional group is introduced into the polymer by using the esterification reaction, urethane reaction, urea reaction, or addition reaction from epoxy. Another process may be usable.

The third layer 18 is most preferably a polymer which is made of polyethylene dioxithiophene acid (PEDOT)/polystyrene sulfonic acid(PSS) as a platform, sulfonic acid base (—SO₃-M⁺ (M⁺ being alkali metal ions)) introduced into the platform. In such a case, sulfonic acid ions and positive ions are paired in order to supply ions necessary for the oxidation and reduction of the EC layer. The foregoing materials are used as high polymer conductive materials and hole transport materials for organic EL. Further, polythiophene, poly-aniline, polyisothia-naphthene, and polypyrrole are usable.

### (2) Layer in Which the Polyether Group Polymer and Support Salt are Dispersed:

Positive ions supplied by the support salt become coordinate in oxide atoms of the polyether group polymer. When a voltage is applied in this state, ions become coordinate with adjacent oxide atoms, move to the EC layer, and supply ions necessary for the oxidation and reduction of the EC layer. The thick polyether group polymer usually transmits few cation or anion radicals of the ECL material molecules or ECL materials.

Specific examples of the polyether group polymers are polyethylene oxides, polypropylene oxides, and poly-butylenes oxides. Polyethylene oxides are o-dichlorobenzene and dimethoxyethane, which are difficult to dissolve in the solvent, are slow to break down and remain stable even when brought into contact with the ECL layer, and are very thick. Therefore, these materials can prevent invasion of cation or anion radicals of the ECL molecules or ECL materials.

The following are usable as the support salt dispersed in the polyether group polymers: lithium fluoride (LiF); sodium iodide (NaI); lithium iodide (LiI); lithium perchlorate (LiClO₄); thiocyanate sodium (NaSCN); trifluoro methane sulfonic acid lithium (LiCF₃SO₃), boric fluoride natrium (LiBF₄), lithium hexafluorophosphate (LiPF₆); phosphoric acid (H₃PO₃); sulfuric acid (H₂SO₄); trifluoro methane sulfonic acid; tetra fluoro ethylene sulfonic acid (C₂F₄(SO₃H)₂); hexa fluoro butane sulfonic acid (C₄F₆(SO₃H)₂); lithium chloride (LiCl); and lithium bromide (LiBr).

In the third layer 18, the cross-linker polymers (and the support salt) in the items (1) and (2) or the polyether polymers (and the support salt) are preferably impregnated in a nonwoven fabric, which thickens the third layer 18, and prevents invasion of the cation or anion radicals of the ECL molecules or ECL materials.

The nonwoven fabric is preferably made of polyethylene, polypropylene, acrylic, polyethylene terephthalate, polyether, rayon, and nylon. Especially, polyethylene or polypropylene is most preferable, and is easy to handle.

Specific examples of the display devices will be described in detail.

### EXAMPLE 1

A display device of 2.5-inch-square is fabricated as follows. Each pixel is assumed to include a monochromatic electrochemical element, and is structured as shown in FIG. 3. Each pixel is a 100 μm-square.

In order to make the first substrate 11, a 1000 Å-thick ITO is sputtered on a 1.1-mm thick glass substrate. The first and second electrodes 16 and 17 are patterned on the sputtered 1000 Å thick ITO (1 Å=10⁻¹⁰ m). Silver Ag is sputtered and patterned to a thickness of 1000 Å, so that the reference electrode 41 is completed.

As the second substrate 12, a 1000 Å-thick ITO is made on a glass substrate, on which the third electrode 13is patterned. The surface of the second substrate 12 carrying the third electrode 13 is subject to the UV process, and is spin-coated by poly-tungsten acid perchlorate aqueous solution in the amount of 4 mol/l (as tungsten), so that an approximately 1000 Å-thick EC layer (WO₃ film) 14 is made.

The third layer 18 is prepared as described hereinafter. PEDOT/PSS is coated onto the EC layer (the second layer 14) in a thickness of 0.1 μm using a spin coater. The spin-coated film is dried for 5 minutes on a hot plate at 80° C. In this state, the third layer 18 is completed. 2 μm high spacers are made on the first substrate 11. The first substrate 11 is placed to face with the third layer 18 so that a 2 μm clearance is secured between the first or second electrode 16 or 17 and the third layer 18. An epoxy resin as a sealant is applied around the first substrate 11 except or an inlet. The first substrate 11 is completed as a cell.

The ECL material in the amount of l0mMruburene is dissolved in an electrolyte made of 10 mM LiCF₃SO₃ and 90 mM TBAPF₆ as the support salt which are dissolved in a solvent containing o-DCB (o-dichlorobenzen)/AN (aceto-nitrile)(3/1). The ECL material is filled into the cell, thereby making the ECL layer (the first layer 15).

An Al reflector is pasted onto the cell, so that the display device is completed.

In the cell, the 2 μm clearance is maintained between the third layer 18 and the first or second electrode 16 or 17. A voltage is applied to the cell in such a manner that the first and second electrodes 16 and 17 have the same potential, and the third electrode 13 has either a positive potential or a negative potential. In this state, it is confirmed that the display device colors or becomes colorless. The reflective indication is accomplished only by the EC layer of WO₃, or by the EC phenomenon between the EC layer of WO₃ and the PEDOT/PSS layer (having the EC property) of the third layer 18.

When an AC voltage is applied between the first and second electrodes 16 and 17 with no voltage applied to the third electrode 13, the display device emits yellow light.

In the foregoing example, the display device can repeatedly accomplish the reflective and luminescent indications for a long period time.

### REFERENCE EXAMPLE 1

A display device of 2.5-inch-square is prepared. Each pixel is assumed to include a monochromatic electrochemical element, and is structured as shown in FIG. 3. Each pixel is a 100 μm-square.

In order to make the first substrate 11, a 1000 Å-thick ITO is sputtered on a 1.1-mm thick glass substrate. The first and second electrodes 16 and 17 are patterned on the sputtered 1000 Å-thick ITO. Silver Ag is sputtered and patterned to a thickness of 1000 Å, so that the reference electrode 41 is completed.

As the second substrate 12, a 1000 Å-thick ITO is made on a glass substrate, which is patterned to obtain the third electrode 13. The surface of the second substrate 12 carrying the third electrode 13 is subject to the UV process, and is spin-coated by a poly-tungsten peroxide acid aqueous solution in the amount of 4 mol/l (as tungsten), so that an approximately 1000 Å-thick EC layer (WO₃ film) 14 is made.

An Al reflector is pasted onto the cell, so that the display device is completed.

In the cell, the 2 μm clearance is maintained between the third layer 18 and the first or second electrode 16 or 17. A voltage is applied to the cell in such a manner that the first and second electrodes 16 and 17 have the same potential, and the third electrode 13 has either a positive potential or a negative potential. In this state, it is confirmed that the display device colors or becomes colorless.

When an AC voltage is applied between the first and second electrodes 16 and 17 with no voltage applied to the third electrode 13, the display device emits yellow light.

In the foregoing example, the display device repeatedly accomplishes the reflective and luminescent indications for a short time period.

### REFERENCE EXAMPLE 2

A display device of 2.5-inch-square is prepared. Each pixel is assumed to include a monochromatic electrochemical element, and is structured as shown in FIG. 3. Each pixel is a 100 μm-square.

In order to make the first substrate 11, a 1000 Å-thick ITO is sputtered on a 1.1-mm thick glass substrate. The first and second electrodes 16 and 17 are patterned on the sputtered 1000 Å-thick ITO. Silver Ag is sputtered and patterned to a thickness of 1000 Å, so that the reference electrode 41 is completed.

As the second substrate 12, a 1000 Å-thick ITO is made on a glass substrate, which is patterned to obtain the third electrode 13. The surface of the second substrate 12 carrying the third electrode 13 is subject to the UV process. The PEDOT/PSS is spin-coated using a spin coater on the third electrode 13 in a thickness of 0.1 μm. The spin-coated film is dried for 5 minutes on a hot plate at 80° C., so that an EC layer is made. 2 μm high spacers are made on the first substrate 11. The first substrate 11 is placed to face with the third layer 18 so that a 2 μm clearance is secured between the first or second electrode 16 or 17 and the third layer 18. An epoxy resin as a sealant is applied around the first substrate 11 except or an inlet. The first substrate 11 is completed as a cell.

The ECL material in the amount of 10 mMruburene is dissolved in an electrolyte made of 10 mM LiCF₃SO₃ and 90 mM TBAPF₆ as the support salt which are dissolved in a solvent containing o-DCB (o-dichlorobenzen)/AN (aceto-nitrile)(3/1). The ECL material is filled into the cell, thereby making the ECL layer (the first layer 15).

An Al reflector is pasted onto the cell, so that the display device is completed.

In the cell, the 2 μm clearance is maintained between the third layer 18 and the first or second electrode 16 or 17. A voltage is applied to the cell in such a manner that the first and second electrodes 16 and 17 have the same potential, and the third electrode 13 has either a positive potential or a negative potential. In this state, it is confirmed that the display device colors or becomes colorless. The PEDOT/PSS functions as the EC layer.

When a voltage is applied between the first and second electrodes 16 and 17 with no voltage applied to the third electrode 13, the display device emits yellow light.

In the foregoing reference example, the display device repeatedly accomplishes the reflective and luminescent indications for a short period time.

### EXAMPLE 2

A further display device is similar to the display devices in the Example 1 and Reference Example 1, but differs from them in the following respects. The third layer 18 and ECL layer (first layer 15) are made as follows.

A solution is prepared by mixing polyethylene oxide (having an average molar amount 6000) and 0.04-mol LiCF₃SO₃/ion dissolving group (ethylene oxide) into aceto-nitrile. The solution is coated on the EC layer (second layer 14) to a thickness of 6 μm using a die coater, and is dried at 80° C., thereby obtaining the third layer 18 of a cell.

Poly [9,9.-bis(3,6-dioxaheptyl)-fluorine-2,7-diyl] (BDOH-PF) is dissolved into ortho-dichlorobenzene so that the former occupies 5%, and is filled into the cell, thereby obtaining the ECL layer (first layer 15).

In the cell, there is a 2 μm clearance between the third layer 18 and the first electrode 16 or the second electrode 17. The first and second electrodes 16 and 17 have the same potential. A voltage is applied to the reference electrode 41 such that the third electrode 13 has either a positive or negative potential. This display device colors or becomes colorless.

When an AC voltage is applied between the first and second electrodes 16 and 17 with no voltage applied to the third electrode 13, the display device emits blue light.

### EXAMPLE 3

A display device is similar to the display device in the Example 2, but differs from it in the following respects. The third layer 18 is made as follows.

Di-vinyl benzene and styrene-sulforate are impregnated into a 10 μm thick nonwoven fabric made of polyethylene, which is heated and is subject to thermal polymerization, thereby obtaining a thin film which is made of the 10 μm thick nonwoven fabric containing a polymer of styrene having a sulfonyl group and di-vinyl benzene. The thin film is cut to a size of a cell, and is placed on the EC layer (the second layer 14).

In the cell, there is a 2 μm clearance between the third layer 18 and the first electrode 16 or the second electrode 17. The first and second electrodes 16 and 17 have the same potential. A voltage is applied to the reference electrode 41 such that the third electrode 13 has either a positive or negative potential. This display device colors or becomes colorless.

When an AC voltage is applied between the first and second electrodes 16 and 17 with no voltage applied to the third electrode 13, the display device emits blue light.

What is claimed is:

1. A display device comprising:
a first substrate;
a first electrode and a second electrode placed on the first substrate;
a second substrate separately placed from and facing with the first substrate;
a third electrode placed on the second substrate;
a first layer placed between the first and second substrates, being on the first substrate, and including a luminescent material which becomes luminous in response to electrochemical oxidation or reduction;
a second layer placed between the first and second substrates, being on the second substrate, and including a coloring material which discolors in response to electrochemical oxidation or reduction; and
a third layer placed between the first and second layers, transmitting none of or few oxidizing species or reducing species in the luminescent material, and having ion conductivity and electron conductivity.

2. A display device comprising:
a first substrate;
a first electrode and a second electrode placed on the first substrate;
a second substrate separately placed from and facing with the first substrate;
a third electrode placed on the second substrate;
a first layer placed between the first and second substrates, being on the first substrate, and including a luminescent material which becomes luminous in response to electrochemical oxidation or reduction;
a second layer placed between the first and second substrate, being on the second substrate, and including a coloring material which discolors in response to electrochemical oxidation or reduction; and
a third layer placed between the first and second layers, and including a cross-linker transmitting none of or few oxidizing species or reducing species in the luminescent material.

3. The display device defined in claim 1, wherein the third layer includes support salt dispersed therein.

4. The display device defined in claim 2, wherein the third layer father includes support salt dispersed therein.

5. The display device defined in claim 2, wherein the cross-linker constituting the third layer is sulfonic acid group which is an ion dissociation group.

6. The display device defined in claim 3, wherein a cross - linker constituting the third layer is sulfonic acid group which is an ion dissociation group.

7. The display device defined in claim 2, wherein the cross-linker is impregnated into a nonwoven fabric.

8. The display device defined in claim 1, wherein the third layer is polyethylene dioxithiophene (PEDOT)/polystyrene sulfonic acid (PPS) which is a thiophene derivative.

9. The display device defined in claim 2, wherein the third layer is polyethylene dioxithiophene (PEDOT)/polystyrene sulfonic acid (PPS) which is a thiophene derivative.

10. The display device defined in claim 1, wherein the third layer includes polyether polymer and dispersed support salt.

11. The display device defined in claim 1, wherein the third layer includes polyether polymer.

12. The display device defined in claim 10, wherein polyether polymer is polyethylene oxide.

13. The display device defined in claim 11, wherein polyether polymer is polyethylene oxide.

14. The display device defined in claim 10, wherein the third layer is a nonwoven fabric in which the support salt and polyether polymer are impregnated.

15. The display device defined in claim 11, wherein the third layer is a nonwoven fabric in which the polyether polymer are impregnated.

16. The display device defined in claim 1, wherein the third layer includes lithium salt.

17. The display device defined in claim 2, wherein the third layer includes lithium salt.

18. The display device defined in claim 1, wherein the first and second electrode are separated from the third layer by a distance of 2 μm or shorter.

19. The display device defined in claim 2, wherein the first and second electrode are separated from the third layer by a distance of 2 μm or shorter.
